(19) United States
(12) Patent Application Publication
(10) Pub. No.: US 2007/0080397 A1
(43) Pub. Date: Apr. 12, 2007

(54) Semiconductor device including field effect transistor having asymmetric structure and method of manufacturing the same

(75) Inventor: Kazutaka Manabe, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY INC.

(21) Appl. No.: 11/542,124

(22) Filed: Oct. 4, 2006

(30) Foreign Application Priority Data
Oct. 7, 2005 (JP) 2005-294698

(51) Int. Cl. H01L 29/76; H01L 21/336

(52) U.S. Cl. 257/335; 257/336; 438/306; 257/E29.128

(57) ABSTRACT

An objective of the present invention is to provide a semiconductor device capable of suppressing generation of the hot carriers while reducing resistance in a drain region, and a method of manufacturing the same. Specifically, the present invention provides a semiconductor device including a field effect transistor comprising a source region and a drain region in the surface region of a semiconductor silicon substrate, characterized in that the drain region has a multiple impurity diffusion layer including at least a first conductivity type impurity diffusion layer and a second conductivity type impurity diffusion layer, and a bird's beak provided on the side of the drain region of the lower part of a gate electrode provided is larger than a bird's beak provided on the side of the source region of the lower part of the gate electrode.

### BACKGROUND OF THE INVENTION

1. Field of the Invention

The present invention relates to a semiconductor device and a method of manufacturing the same, and more specifically, relates to a semiconductor device including a field effect transistor in which the structure of an impurity diffusion layer on the side of a source region provided in the surface region of a semiconductor silicon substrate, and the structure of an impurity diffusion layer on the side of a drain region provided in the surface region of the semiconductor silicon substrate are asymmetrical, and a method of manufacturing the same.

2. Related Art

As reduction in size and weight and reduction of electric power consumption of electronic equipment are progressing in recent years, there are increasing demands for higher density and further reduction in the electric power consumption of semiconductor devices including a field effect transistor.

For the purpose of reducing resistance in the drain region and the like of the field effect transistor, a semiconductor device is proposed in which the structure of an impurity diffusion layer on the side of a source region provided in a semiconductor silicon substrate and the structure of an impurity diffusion layer on the side of a drain region provided in the semiconductor silicon substrate are asymmetrical.

The above semiconductor device is described with reference to a figure as follows.

FIG. 9 is a schematic cross section of an essential part of a semiconductor device in which the structures of impurity diffusion layers 930 and 931 on the side of a source region provided in the surface region of a silicon substrate 1, and the structures of impurity diffusion layers 940 and 941 on the side of a drain region provided in the surface region of the silicon substrate 1 are asymmetrical with each other. A reference numeral 300 represents a gate electrode.

According to the semiconductor device shown in FIG. 9, the resistance of the drain region can be reduced by making the structures of the impurity diffusion layers asymmetrical as described above (Japanese Patent Application publication 2002-343806).

### BRIEF SUMMARY OF THE INVENTION

However, the structure of the semiconductor device shown in FIG. 9 makes a problem of hot carriers in the semiconductor silicon substrate no more negligible as the semiconductor device becomes smaller.

An objective of the present invention is to provide a semiconductor device capable of suppressing generation of the hot carriers while reducing resistance in a drain region, and a method of manufacturing the same.

The result of intensive investigations of the present inventor shows that the objective of the present invention can be attained by a semiconductor device in which the structure of an impurity diffusion layer on the side of a source region provided in a surface region of a semiconductor silicon substrate, and the structure of an impurity diffusion layer on the side of a drain region provided in the surface region of the semiconductor silicon substrate are asymmetrical, and a bird's beak formed on the side of the drain region of a lower part of a gate electrode is larger than a bird's beak formed on the side of the source region of the lower part of the gate electrode.

More specifically, the present invention provides:

[1] a semiconductor device comprising a semiconductor silicon substrate,

a gate electrode provided on the semiconductor silicon substrate via a gate oxide film,

a couple of regions, namely, a source region and a drain region provided on both sides of the gate electrode in the surface region of the semiconductor silicon substrate,

a source elevation structure and a drain elevation structure provided on the semiconductor silicon substrate,

a first sidewall spacer provided on the side of the source region of the gate electrode, and

bird's beaks consisting of a silicon oxide film individually provided on the sides of the source region and the drain region of the lower part of the gate electrode, the semiconductor device being characterized in that

the drain region has a multiple impurity diffusion layer including at least a first conductivity type impurity diffusion layer and a second conductivity type impurity diffusion layer, and

the bird's beak on the side of the drain region is larger than the bird's beak on the side of the source region.

Further, the present invention provides:

[2] the semiconductor device as described in the item [1], characterized by comprising a field effect cell transistor for DRAMs.

Furthermore, the present invention provides:

[3] a method of manufacturing a semiconductor device, characterized by comprising

a step of forming a gate electrode on a semiconductor silicon substrate via a gate oxide film,

a step of forming a couple of regions, namely, a source region and a drain region on both sides of the gate electrode in the surface region of the semiconductor silicon substrate,

a step of forming a first sidewall spacer on the side of the source region, and a second sidewall spacer on the side of the drain region with respect to the gate electrode,

a step of forming a source elevation structure and a drain elevation structure being respectively in contact with the source region and the drain region on the semiconductor silicon substrate,

a step of removing the second sidewall spacer formed on the side of the drain region according to an etching operation,

a step of forming a multiple impurity diffusion layer including at least a first conductivity type impurity diffusion layer and a second conductivity type impurity diffusion layer on the drain region, and

a step of forming a bird's beak larger than a bird's beak on the side of the source region of a lower part of the gate electrode, on the side of the drain region of the lower part of the gate electrode.

According to the present invention, the semiconductor device capable of suppressing generation of the hot carriers while reducing the resistance in the drain region, and the method of manufacturing the same can be provided.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a schematic cross section of an essential part for illustrating one embodiment of a semiconductor device according to the present invention;

FIG. 2 is a partial cross section of an essential part showing the enlarged essential part of a gate electrode 300 in FIG. 1;

FIG. 3 is a schematic cross section of an essential part for describing a step of manufacturing the gate electrode part of the semiconductor device according to the present invention;

FIG. 4 is a schematic cross section of an essential part for describing a step of manufacturing a sidewall spacer part of the semiconductor device according to the present invention;

FIG. 5 is a schematic cross section of an essential part for describing a step of providing a resist film on an upper position of a hard mask provided in the upper part of the semiconductor device according to the present invention;

FIG. 6 is a schematic cross section of an essential part for describing a step of removing a sidewall spacer on the side of a bit line, that is, on a side where an extension as a drain region was formed;

FIG. 7 is a schematic cross section of an essential part for illustrating one embodiment of a semiconductor device according to the present invention (Example 1);

FIG. 8 is a schematic cross section of an essential part showing one embodiment of a semiconductor device (Comparative Example 1); and

FIG. 9 is a schematic cross section of an essential part of a semiconductor device in which the structure of the impurity diffusion layer on the side of a source region, and the structure of the impurity diffusion layer on the side of a drain region are asymmetrical with each other.

### DETAILED DESCRIPTION OF THE INVENTION

First, a semiconductor device according to the present invention is described with reference to the drawings.

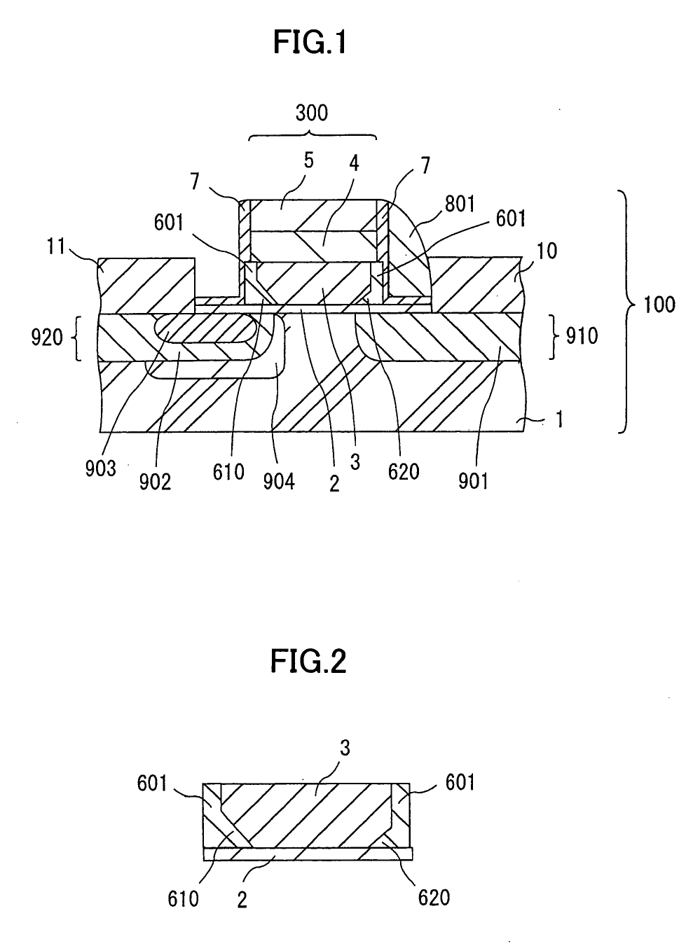

FIG. 1 illustrates a schematic cross section of an essential part for one embodiment of a semiconductor device 100 according to the present invention.

As a semiconductor silicon substrate 1 used for the present invention, a p-type semiconductor silicon substrate containing an impurity such as boron may be cited.

A gate oxide film 2 formed of silicon oxide and the like is provided on the surface of the semiconductor silicon substrate 1, and a gate electrode 300 is provided via the gate oxide film 2.

The thickness of the gate oxide film 2 is normally in the range of 1 to 20 nm.

In the gate electrode 300, a polysilicon film 3, a nitrogen-containing insulating film 4 formed of silicon nitride and the like, and an upper oxide film 5 formed of silicon oxide and the like are individually provided.

The thickness of the polysilicon film 3 is normally in the range of 30 to 200 nm.

Moreover, the thickness of the nitrogen-containing insulating film 4 is normally in the range of 20 to 300 nm, and the thickness of the upper oxide film 5 is normally in the range of 20 to 300 nm.

The polysilicon film 3 may be constituted by polysilicon containing a p-type impurity such as boron, and polysilicon containing an n-type impurity such as phosphorus.

Although not specifically shown in FIG. 1, a tungsten silicide film, a tungsten/tungsten nitride film and the like may be provided on the polysilicon film 3. Salicide treatment may be applied suitably to the polysilicon film 3 for any purpose.

An oxide film 601 such as a silicon oxide film is provided on the sidewall of the polysilicon film 3. The thickness of the oxide film 601 is normally in the range of 0.5 to 30 nm. Bird's beaks 610 and 620 formed by growth of silicon oxide and the like are respectively provided on both ends of the lower part of the polysilicon film 3. The oxide film 601 and the bird's beak 620 on the sidewall of the polysilicon film 3 can be omitted.

In the semiconductor device according to the present invention, the bird's beak 610 on the side of the drain region 920 is required to be larger than the bird's beak 620 on the side of the source region 910.

The size of each of the bird's beak 610 and the bird's beak 620 can be determined, as illustrated in FIG. 1, from a ratio of an area occupied by the silicon oxide in the lower part of the gate electrode 300 to the area of a section formed by vertically cutting the semiconductor silicon substrate 1.

FIG. 2 is a partial cross section of an essential part obtained by extracting and enlarging parts corresponding to the polysilicon film 3, the oxide film 601, the bird's beak 610, the bird's beak 620 of the gate electrode 300, and the gate oxide film 2 in FIG. 1.

The size of each of the bird's beaks 610 and 620 can be relatively easily determined when the bird's beaks 610 and 620 are clearly appearing as shown in FIG. 2. For example, even when the oxide film 601 has significantly grown, the size can be determined by comparing the cross section area of a part corresponding to the bird's beak 610 of the polysilicon film 3 in the lower part of the gate electrode with the cross section area of a part corresponding to the bird's beak 620 of the polysilicon film 3 in the lower part of the gate electrode.

For example, when taking the case of FIG. 2, the cross section area of the part corresponding to the bird's beak 610 is found to be larger than the cross section area of the part corresponding to the bird's beak 620.

Accordingly, as far as this case is concerned, the bird's beak 610 is regarded to be larger than the bird's beak 620.

Returning to FIG. 1 again, a construction of the semiconductor device according to the present invention is described.

Sidewall oxide films 7 consisting of silicon oxide and the like formed by a chemical vapor deposition (CVD) method or the like are provided on the sidewalls of the gate electrode 300, respectively.

The thickness of each of the sidewall oxide films 7 is normally in the range of 2 to 20 nm.

A first sidewall spacer 801 is provided on one side of the gate electrode 300 via the sidewall oxide film 7.

Moreover, a couple of regions, namely, a source region 910 and a drain region 920, are provided on both sides of the gate electrode 300 in the surface region of the silicon substrate 1.

A first impurity diffusion layer containing an n-type impurity such as phosphorus is provided in the source region 910. As the first impurity diffusion layer, as illustrated in FIG. 1, an extension 901 is provided in the surface area of the semiconductor silicon substrate 1.

The extension 901 is normally provided to have a depth in the range of 10 to 200 nm from the surface of the semiconductor silicon substrate 1.

The amount of the n-type impurity such as phosphorus to be implanted and contained in the extension 901 is normally in the range of 1×10¹² to 1×10¹⁴/cm².

On the other hand, the drain region 920 is provided with a first impurity diffusion layer containing the n-type impurity such as phosphorus as well as a second impurity diffusion layer containing the n-type impurity such as phosphorus formed inside the first impurity diffusion layer, and a third impurity diffusion layer containing a p-type impurity such as boron formed so as to surround the first impurity diffusion layer, and the like which constitute a multiple impurity diffusion layer.

The construction of the multiple impurity diffusion layer of this kind is determined appropriately depending on use of the semiconductor device to be obtained and the like. One embodiment of the multiple impurity diffusion layer is provided with an extension 902 as the first impurity diffusion layer, an extension 903 as the second impurity diffusion layer, and a pocket 904 as the third impurity diffusion layer in the surface region of the semiconductor silicon substrate 1, as illustrated in FIG. 1.

Generally, the multiple impurity diffusion layer includes at least a fist conductivity type impurity diffusion layer and a second conductivity type impurity diffusion layer.

The amount of n-type impurity such as phosphorus to be implanted and contained in the extension 902 is similar to that of the extension 901 as described above.

Moreover, the amount of n-type impurity such as phosphorus to be implanted in forming the extension 903 is normally in the range of 1.0×10¹² to 1.0×10¹⁴/cm².

The amount of p-type impurity such as boron to be implanted in forming the pocket 904 is normally in the range of 1.0×10¹² to 1.0×10¹⁴/cm².

On the other hand, a source elevation structure 10 and a drain elevation structure 11 provided by causing semiconductor silicon to grow from the surface of the semiconductor silicon substrate 1 by a selective epitaxial growth method are provided on the semiconductor silicon substrate 1.

The height of each of the source elevation structure 10 and the drain elevation structure 11 is normally in the range of 20 to 200 nm from the surface of the semiconductor silicon substrate 1.

Into the source elevation structure 10 and the drain elevation structure 11, an n-type impurity such as phosphorus is introduced by an ion implantation method or the like. An amount of implantation in this case is normally in the range of 1.0×10¹³ to 5.0×10¹⁵/cm².

Although not specifically illustrated, a publicly known structure such as an interlayer insulating film, a contact plug, and metallic wiring is provided for the semiconductor silicon substrate 1 as appropriate, and thus the semiconductor device having the construction as described above according to the present invention is allowed to operate as a field effect transistor.

The present invention is not limited by the numerical values used for description.

In particular, the semiconductor device according to the present invention can be favorably used specifically as a semiconductor device including a field effect cell transistor for DRAMs.

Next, the semiconductor device according to the present invention is described in more detail with reference to Examples. However, the present invention is by no means limited by these Examples.

### EXAMPLE 1

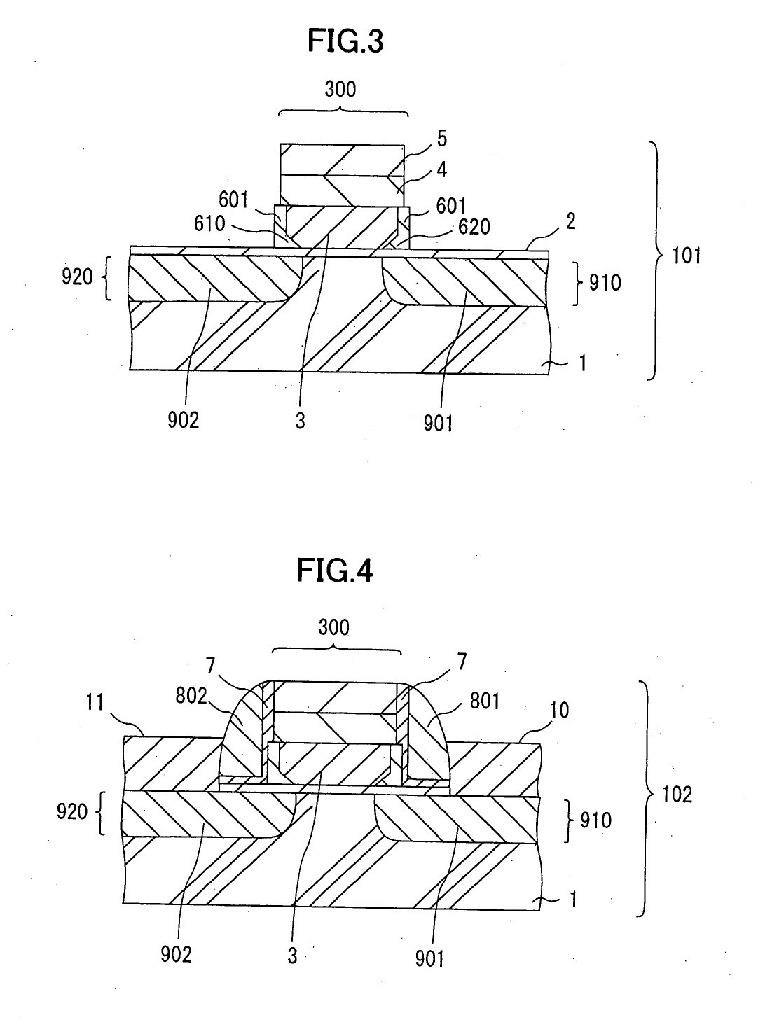

FIG. 3 is a schematic cross section of an essential part for describing a step of manufacturing a gate electrode part of a semiconductor device according to the present invention.

First, a semiconductor silicon substrate 1 containing boron as a p-type impurity was prepared. The surface of the semiconductor silicon substrate 1 was allowed to react with steam at high temperature, and thus a gate oxide film 2 having a thickness of 7 nm and consisting of silicon oxide was formed. Subsequently, a polysilicon film 3 having a thickness of 100 nm was formed on the gate oxide film 2 by causing silicon to deposit thereon by a CVD method.

Phosphorus is contained in the polysilicon film 3 as an impurity by causing phosphorus to mix therein when applying the CVD method.

A nitrogen-containing insulating film 4 consisting of silicon nitride and an upper oxide film 5 consisting of silicon oxide were sequentially formed on the polysilicon film 3.

Next, a resist film was provided on the upper oxide film 5 to serve as the mask, and thus an unnecessary part of each of the upper oxide film 5, the nitrogen-containing insulating film 4, and the polysilicon film 3 was removed according to a publicly known etching technique.

Subsequently, a sidewall of the polysilicon film 3 was allowed to react with steam at high temperature, and oxidized, and thus an oxide film 601 consisting of silicon oxide was formed. The thickness of this oxide film 601 was in the range of 5 to 10 nm.

During the oxide film formation, bird's beaks 610 and 620 each consisting of silicon oxide were formed on both ends of the lower part of the polysilicon film 3. The size of each of the bird's beaks 610 and 620 during the formation was substantially identical.

Subsequently, the gate electrode 300 including the polysilicon film 3, the nitrogen-containing insulating film 4, and the upper oxide film 5 was used as the mask, and a phosphorus ion was introduced into the semiconductor silicon substrate 1 in an amount of implantation to 1.0×10¹³/cm²by an ion implantation method in a self-alignment manner, and thus extensions 901 and 902 were individually formed on both sides of the gate electrode 300 in the surface region of the semiconductor silicon substrate 1.

Through the operation as described above, the structure of the semiconductor device 101 shown in the schematic cross section of the essential part in FIG. 3 is obtained.

FIG. 4 is a schematic cross section of an essential part for describing a step of manufacturing a sidewall spacer part of a semiconductor device according to the present invention.

First, a silicon oxide film having a thickness of 10 nm was provided on the upper surface of the gate electrode 300 and the gate oxide film 2 by the CVD method.

Subsequently, a silicon nitride film was caused to deposit on the semiconductor silicon substrate 1 by the CVD method, and then, as shown in FIG. 4, sidewall oxide films 7, and sidewall spacers 801 and 802 consisting of silicon nitride were formed.

Next, an unnecessary silicon oxide film on the semiconductor silicon substrate 1 was removed by an etching operation, and then semiconductor silicon was caused to grow from the surface of the semiconductor silicon substrate 1 by the selective epitaxial growth method, and, as shown in FIG. 4, a source elevation structure 10 and a drain elevation structure 11 were formed.

Phosphorus was introduced by the ion implantation method into the source elevation structure 10 and the drain elevation structure 11 in an amount of implantation to 1.0×10¹⁴/cm².

Through the operation as described above, the structure of the semiconductor device 102 shown in the schematic cross section of the essential part in FIG. 4 is obtained.

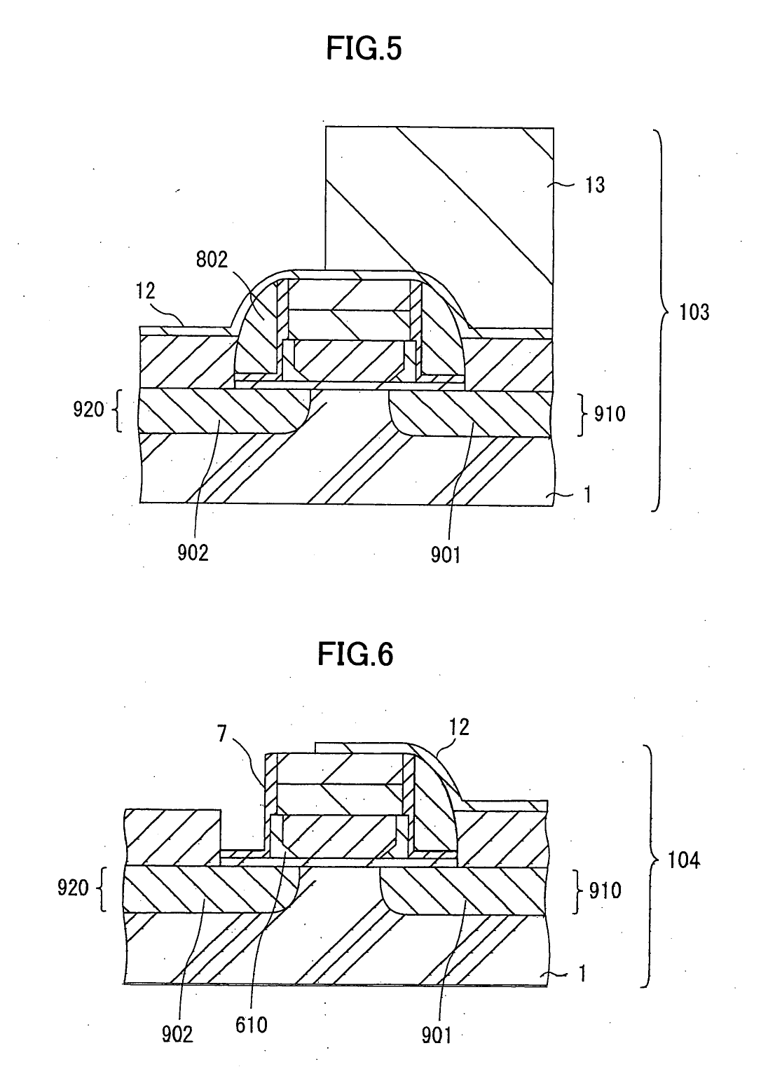

FIG. 5 is a schematic cross section of an essential part for describing a step of providing a resist film 13 on an upper position of a hard mask 12 provided on the upper part of the semiconductor device according to the present invention.

The hard mask 12 consisting of silicon oxide was formed by the CVD method on the upper part of the semiconductor device, and the resist film 13 was further provided on the upper position shown in FIG. 5.

Through the operation as described above, the structure of the semiconductor device 103 shown in the schematic cross section of the essential part in FIG. 5 is obtained.

FIG. 6 is a schematic cross section of an essential part for describing a step of removing a sidewall spacer 802 on a side of a bit line, that is, on a side where an extension 902 to constitute a drain region has been formed.

First, using the resist film 13 as the mask, the hard mask 12 was removed by etching, and then the resist film 13 was removed. Then, the sidewall spacer 802 consisting of silicon nitride was removed by a wet etching method using hot phosphoric acid. At this time, the sidewall spacer 801 on the side of the source region is covered with the hard mask 12, and therefore remains intact without being removed.

Through the operation as described above, the structure of the semiconductor device 104 shown in the schematic cross section of the essential part in FIG. 6 is obtained.

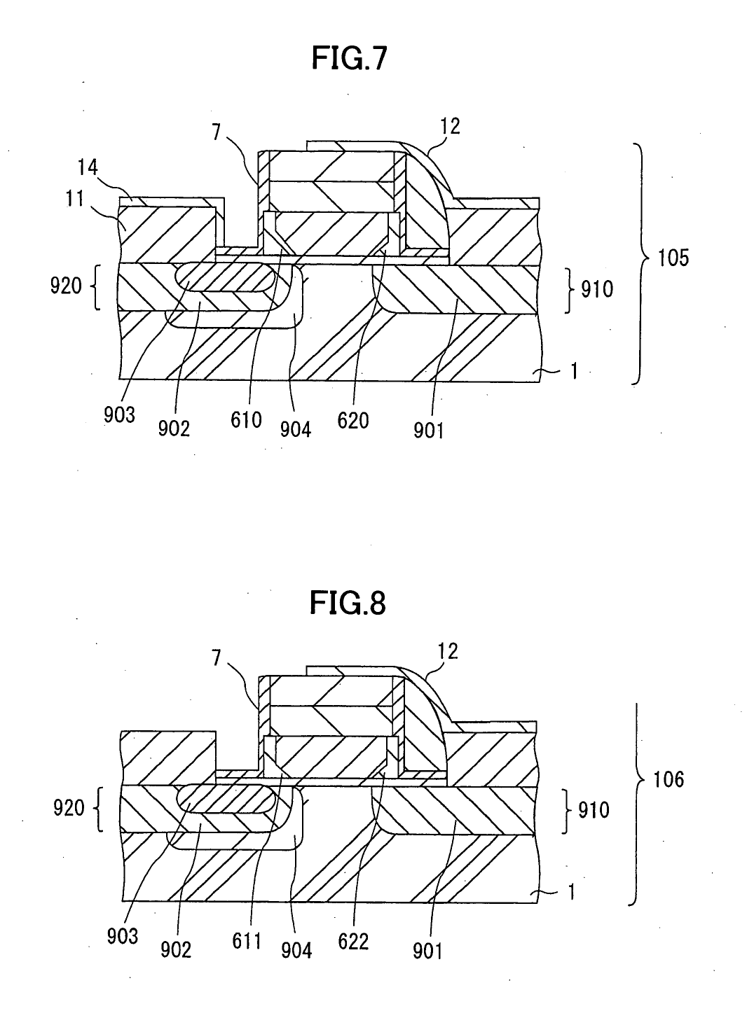

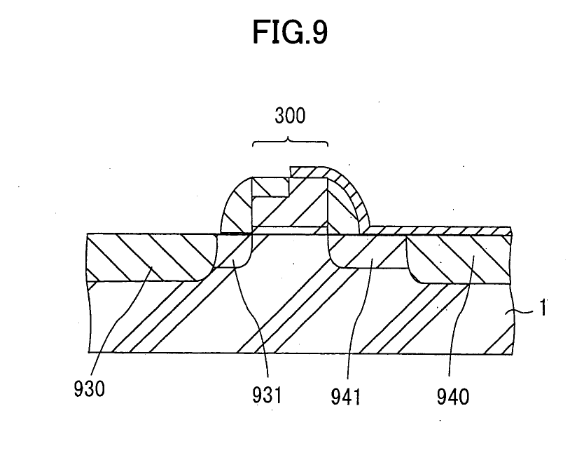

Next, as shown in FIG. 7, the gate electrode 300 was allowed to react with steam at high temperature, and thus the bird's beak 610 was caused to grow in the lower part of the gate electrode on the side of the drain region. At this time, the sidewall spacer 801 consisting of silicon nitride remains on the side of the source region, and therefore a part on the side of the source region is not oxidized, and the bird's beak 620 in the lower part of the gate electrode does not grow.

Accordingly, the bird's beak formed on the side of the drain region of the lower part of the gate electrode becomes larger than the bird's beak formed on the side of the source region of the lower part of the gate electrode.

In order to effectively cause the bird's beak 610 to grow, the sidewall oxide film 7 in the vicinity of the bird's beak 610 may be removed.

With the treatment, a thermal oxide film 14 is formed on the surface of the drain elevation structure 11. Thus, as shown in FIG. 7, a structure of the semiconductor device 105 having the bird's beak 610 larger than the bird's beak 620 is obtained.

Subsequently, phosphorus was introduced by the ion implantation method in an amount of implantation to 1.0×10¹³/cm², and thus the extension 903 as the second impurity diffusion layer was formed so as to be located inside the first impurity diffusion layer consisting of the extension 902. In a similar manner, boron was introduced by the ion implantation method by setting an amount of implantation to 1.0×10¹³/cm², and thus the pocket 904 as the third impurity diffusion layer was formed so as to surround the first impurity diffusion layer of the extension 902. Here, sequences of forming the second impurity diffusion layer and the third impurity diffusion layer maybe reversed. Furthermore, a position of forming the impurity diffusion layers can be controlled appropriately depending on ion implantation conditions or heat-treatment conditions for causing ions to diffuse. Moreover, arsenic may be used instead of phosphorus as an impurity for forming the extension 903.

Through the operation as described above, as shown in FIG. 7, the extension 901 can be formed as the source region 910 in the surface region of the semiconductor silicon substrate 1.

In a similar manner, a multiple impurity diffusion layer including the extension 902, the extension 903 and the pocket 904 can be formed as the drain region 920.

Generally, the multiple impurity diffusion layer includes at least a first conductivity type impurity diffusion layer and a second conductivity type impurity diffusion layer.

Then, an interlayer insulating film is formed on the entire part, the interlayer insulating film and the thermal oxide film 14 on the drain elevation structure 11 are removed, and a contact plug is provided, thereby forming bit-line wiring and the like as appropriate (not shown).

A DRAM having a field effect cell transistor of the structure of the semiconductor device 105 operated stably without producing a problem of hot carriers.

### COMPARATIVE EXAMPLE 1

As shown in FIG. 8, a semiconductor device 106 was manufactured in a manner completely similar to Example 1 except that the operation for causing the bird's beak 610 to grow in the case of Example 1 was not performed, and thus the semiconductor device 106 having substantially symmetrical bird's beaks 611 and 622 was manufactured.

The DRAM having a field effect cell transistor of the structure of the semiconductor device 106 operated unstably with producing a problem of hot carriers.

The present invention is not limited to the above described embodiments, and various variations and modifications may be possible without departing from the scope of the present invention.

This application is based on the Japanese Patent application No. 2005-294698 filed on Oct. 7, 2005, entire content of which is expressly incorporated by reference herein.

What is claimed is:

1. A semiconductor device comprising:
a semiconductor silicon substrate;
a gate electrode provided on the semiconductor silicon substrate via a gate oxide film;
a source region and a drain region provided in a pair on respective sides of the gate electrode in the surface area of the semiconductor silicon substrate;
a source elevation structure and a drain elevation structure provided on the semiconductor silicon substrate;
a first sidewall spacer provided on a source region side of the gate electrode; and
bird's beaks consisting of a silicon oxide film provided on the source region side and a drain region side, respectively, of a lower part of the gate electrode,
the drain region having a multiple impurity diffusion layer including at least a first conductivity type impurity diffusion layer and a second conductivity type impurity diffusion layer, and
the bird's beak on the drain region side is larger than the bird's beak on the source region side.

2. The semiconductor device as described in claim 1, comprising a field effect cell transistor for DRAMs.

3. A method of manufacturing a semiconductor device, comprising:
a step of forming a gate electrode on a semiconductor silicon substrate via a gate oxide film;
a step of forming a pair of a source region and a drain region on respective sides of the gate electrode in a surface region of the semiconductor silicon substrate;
a step of forming a first sidewall spacer on a source region side and a second sidewall spacer on a drain region side of the gate electrode;
a step of forming a source elevation structure and a drain elevation structure in contact with the source region and the drain region, respectively, on the semiconductor silicon substrate;
a step of removing the second sidewall spacer formed on the drain region side by an etching operation;
a step of forming a multiple impurity diffusion layer including at least a first conductivity type impurity diffusion layer and a second conductivity type impurity diffusion layer on the drain region; and
a step of forming a bird's beak on each of the drain region side and the source region side of a lower part of the gate electrode in such a manner that the bird's beak on the drain region side is larger than the bird's beak on the source region side.
